(19) United States
(12) Patent Application Publication
(10) Pub. No.: US 2015/0039956 A1
(43) Pub. Date: Feb. 5, 2015

(54) TEST MUX FLIP-FLOP CELL FOR REDUCED SCAN SHIFT AND FUNCTIONAL SWITCHING POWER CONSUMPTION

(71) Applicant: STMicroelectronics Asia Pacific Pte. Ltd., Singapore (SG)

(72) Inventor: Beng-Heng Goh, Singapore (SG)

(73) Assignee: STMicroelectronics Asia Pacific Pte. Ltd., Singapore (SG)

(21) Appl. No.: 13/954,227

(22) Filed: Jul. 30, 2013

(51) Int. Cl. G01R 31/3177

(52) U.S. Cl. CPC G01R 31/3177
USPC 714/729

(57) ABSTRACT

A new flip-flop cell that is more efficient in scan chain configuration includes a multiplexer, storage element (e.g., a flip-flop), an inverter, and multiple logic gates. The flip-flop cell is configured to receive both a test signal and a data input signal and select one of the two to pass to the storage element based on a scan enable signal that indicates either a capture mode or a scan shift mode. In capture mode, the data input signal is passed to the storage element, and the internal outputs of the flip-flop are supplied to the logic gates. Based on the internal outputs and scan enable signal, the logic gates disable either one of two outputs of the flip-flop cell. In capture mode, a test flip-flop cell output is disabled. In scan shift mode, a standard function flip-flop cell output is disabled.

### TECHNICAL FIELD

The present patent application relates to scan testing.

### BACKGROUND

Scan tests are widely used to efficiently test the logic of different designs on a chip. An effective scan test can detect a high percentage of manufacturing failures and greatly reduce the amount time and data necessary to ensure a particular chip design is working properly. Scan chains typically operate in two modes: (1) a scan shift mode; and (2) a normal function, or “capture,” mode. In the scan shift mode, a test value is shifted into serially connected flip-flops of the scan chain. In capture mode, the flip-flops are allowed to function properly by passing data to combinational logic of a design under test (DUT) and receiving signals from the DUT as inputs to the next sequential flip-flop in the scan chain. Testing occurs by first shifting the test value into the flip-flops during scan shift mode and then supplying the test value to the DUT during capture mode to see how the DUT responds. The final flip-flop in the chain produces an output value that can be compared against what should have been produced by the DUT, and if the two do not match, the testing strongly indicates that there is a flaw or bug in the DUT.

A D flip-flop has a single data input, a reset input, a clock input, and multiple flip-flop outputs. Upon detection of a particular clock action (e.g., a rising edge), a D flip-flop is designed to assign the value of the data input to a standard function output and a test output. In a scan chain using D flip-flops, the standard function output of each D flip-flop is connected to circuitry of the DUT, and the test output of each D flip-flop is connected to the test input of the next flip-flop in the chain. During capture mode, the test output of the D flip-flop does not matter while the standard function output does because the latter is supplying data values to circuitry of the DUT. Conversely, in scan shift mode, the standard function output of the D flip-flop does not matter while the test output does because the latter is being used to shift in the test value. Even though one of the two D flip-flop outputs do not matter at any given time, signals are still being sent across both outputs. Power is required to switch these unnecessary signals of the two D flip-flop outputs, and this unnecessary signal switching is wasteful for at least one flip-flop output at any given time—not only for the power required to switch the output but also for downstream electrical activity in the IC that may be affected by the unnecessary output.

### SUMMARY

This Summary is provided to introduce a selection of concepts in a simplified form that are further described below in the Detailed Description. This Summary is not intended to identify key features or essential features of the claimed subject matter.

One aspect is directed to a flip-flop cell that includes a multiplexer, flip-flop, and different logic gates. The flip-flop cell has four inputs: a data input, a test input, a scan enable input, and a clock input. The data input and test input are coupled to the multiplexer as inputs, and the enable signal input is coupled to the multiplexer as a selector. The multiplexer passes either the data input signal or the test input signal to an internal data input of a D flip-flop based on the scan enable signal signaling a capture mode or scan shift mode.

The scan enable signal is set to one state (e.g., zero or low) to place the flip-flop cell into capture mode and set to the other logic state (e.g., one or high) to place the flip-flop logic cell into scan shift mode. Capture mode represents a configuration where the data input passed to the multiplexer is fed to the internal data input of the flip-flop, and thereafter transmitted to the internal output of the flip-flop after a particular clock event, such as a rising or falling clock edge. Conversely, scan shift mode instructs the multiplexer to send the test input to the internal data input of the flip-flop, consequently transmitting the test input to the flip-flop's internal output at the next clock event.

Logic gates inside the flip-flop cell receive the internal data signal from the flip-flop in addition to the scan enable signal and subsequently generate a standard function flip-flop cell output and a test flip-flop cell output. At least one embodiment uses an inverter to invert the scan enable signal being provided to one of the logic gates while also passing a functional version of the scan enable signal to the other logic gate.

Another aspect is directed to a scan test configuration design with multiple flip-flop cells connected together in series such that their test flip-flop cell outputs are connected to the test inputs of the next flip-flop in the chain. Each flip-flop cell includes a D flip-flop, multiplexer, and multiple logic gates that collectively operate to disable a standard function flip-flop cell output signal when a scan enable signal is set to scan shift mode, and alternatively disable a test flip-flop cell output when the scan enable signal is set to capture mode. In one embodiment, the test flip-flop cell output of the final flip-flop in the sequence of serially connected flip-flops is provided to peripheral circuitry, logic, or memory in order to store a value or values associated with a scan chain test.

The foregoing and other features and advantages of the present disclosure will become more apparent from the following detailed description of the embodiments read in conjunction with the accompanying drawings. The detailed description and drawings are merely illustrative of some different embodiments, rather than limiting the scope of the invention as defined by the appended claims and equivalents thereof.

### BRIEF DESCRIPTION OF DRAWINGS

Embodiments are illustrated by way of example in the accompanying figures, wherein:

FIG. 1 illustrates a detailed representation of a flip-flop cell; and

FIG. 2 illustrates a detailed representation of multiple flip-flop cells connected in a scan chain configuration.

### DETAILED DESCRIPTION

A scan chain test uses several flip-flop cells connected in series to each other and is configured to operate in two different modes: a scan shift mode and a capture mode. In the scan shift mode, the flip-flops cells in the scan chain series are configured to shift in a test value, one bit at a time, to their outputs, and a test output of the test input is supplied to the next flip-flop in the scan chain series. Once the test value has been shifted into the flip-flop cells, the flip-flops are switched to the capture mode during which testing of the DUT can be performed by passing the test value to the DUT through the flip-flop cells. In capture mode, data input signals from the DUT are received at one or more of the flip-flop cells, passed to a standard function flip-flop cell output, and that standard function cell output is supplied to other circuitry in the DUT. The rest of the flip-flop cells are similarly connected, creating a connection path through the DUT and all the flip-flop cells, and an output of the final flip-flop cell in the scan chain can be analyzed to determine how the logic and circuitry of the DUT is operating.

Embodiments described herein generally relate to a new flip-flop cell that reduces overall switching current and power consumption when used in a scan chain test configuration. The flip-flop cell does so by disabling a standard function flip-flop cell output whenever a scan enable input signal places the flip-flop cell into a scan shift mode and disabling a test flip-flop cell output when the flip-flop cell is placed in a capture mode. Accordingly, one embodiment disables at least one flip-flop cell output based on what mode is specified by the scan enable signal.

Before turning to the drawings, a couple key points should be clarified. First, embodiments discussed herein refer to a flip-flop cells that internally include flip-flops, multiplexers, logic gates, and inverters. The flip-flops themselves have “internal” inputs and outputs themselves that are internal to the flip-flop cells. The flip-flop cells have inputs and outputs as well, and in particular, these outputs are referred to herein as “flip-flop cell outputs.”

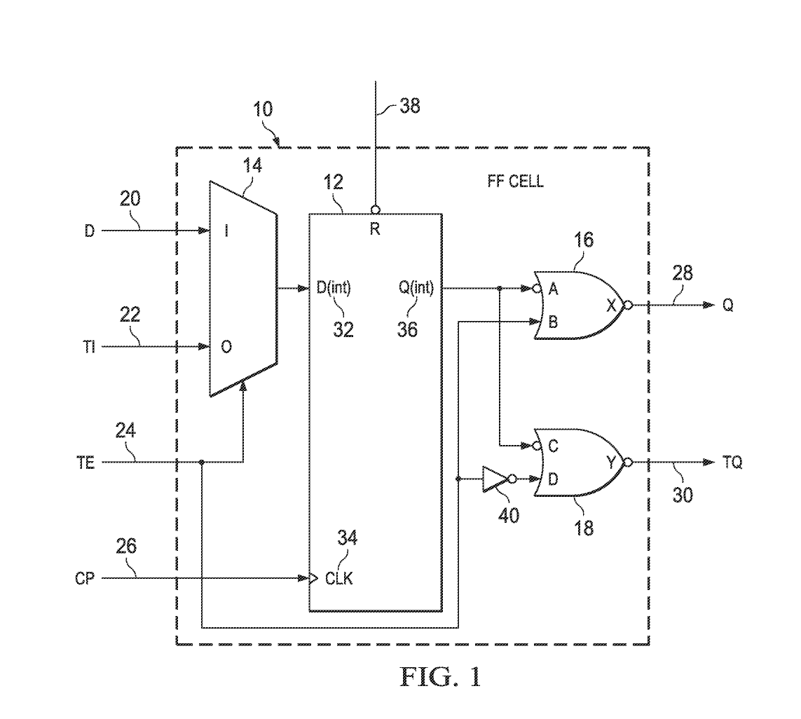

FIG. 1 illustrates a detailed representation of a flip-flop cell 10 that includes a flip-flop 12, a multiplexer 14, and multiple NOR gates 16 and 18. Flip-flop cell 10 includes a data input D 20, a test input TI 22, a scan enable input TE 24, and a clock input CP 26. Based on the data received at those four inputs, flip-flop cell 10 sets the internal flip-flop output signal Q(int) 36 to the current value of internal data input signal D(int) 32 after detection of a specific clock event at clock input CLK 34. Logic gates 16 and 18 use Q(int) 26 and TE 24 to produce flip-flop cell output Q 28 and test flip-flop cell output TQ 30. Clock events may include a rising edge, falling edge, toggle, or other relevant action.

Flip-flop cell 10 operates in two different modes: capture mode and scan shift mode. Modes may be set and changed using scan enable input TE 24. In one embodiment, logic gates 16 and 18 comprise two NOR gates that are supplied with TE 24. Logic gate 16 directly receives TE 24, and logic gate 18 receives an inversion of TE 24 from inverter 40. Logic gates 16 and 18 responsively generate flip-flop cell output Q 28 and test flip-flop cell output TQ 30 based on Q(int) 36 and TE 24 (either inverted by inverter 40 or non-inverted).

In one embodiment, flip-flop 12 is a D flip-flop that receives the multiplexed output at internal data input D(int) 32 and accordingly sets internal data output signal Q(int) 36 to the multiplexed output on the next rising or falling clock edge of CP 26, depending on how flip-flop 12 is configured. Alternative embodiments may use other types of flip-flops, such as SR flip-flops, JK flip-flops, and the like. Moreover, flip-flop 12 can be reset or cleared using reset line 38.

Q(int) 36 is coupled to inputs A and C of logic gates 16 and 18, respectively. TE 24 is coupled to inputs B and D of logic gates 16 and 18, respectively, with the input to B not being inverted while the input to D is inverted by inverter 40. In operation, NOR gates 16 and 18 will generate outputs according to the following table:

TABLE 1
Logic Table for Logic Gates 16 and 18

| Q(int)′ | TE | TE′ | Q | TQ |
|---|---|---|---|---|
| 1 | 0 | 1 | 0 | 0 |
| 1 | 1 | 0 | 0 | 0 |
| 0 | 0 | 1 | 1 | 0 |
| 0 | 1 | 0 | 0 | 1 |

Where Q(int)′ represents Q(int) 36 after being inverted at inputs A and C, TE′ represents inverted TE 24 after inverter 40, and Q and TQ represent the test flip-flop cell outputs (X and Y, respectively) of NOR gates 16 and 18. This configuration allows flip cell 10 to enable and disable Q or TQ based on the TE 24 being set to 0 (indicating capture mode) and 1 (indicating scan shift mode). Of course, alternative embodiments may use opposite values to place flip-flop cell 10 into capture and scan chain mode (i.e., 1 for capture and 0 for scan chain).

With respect to embodiments discussed herein, “disabling” a particular flip-flop cell output refers to setting that cell output to a particular value (such as “0” in some embodiments or “1” in other embodiments) and maintaining that value until the scan enable signal switches the flip-flop cell out of a current mode. For example, TQ 30 is disabled while TE 24 is in a low state to indicate capture mode, during which Q 28 is allowed to toggle between high and low values. Conversely, after TE 24 is driven high indicating scan shift mode has been initiated, TQ 30 is allowed to switch between high and low values while Q 28 is disabled. Keeping one flip-flop cell output constant saves a large amount of power and current that would be expended by continually switching the flip-flop cell output from one value to another, which also saves power that would be used downstream by logic and circuitry connected to the disabled flip-flop cell output.

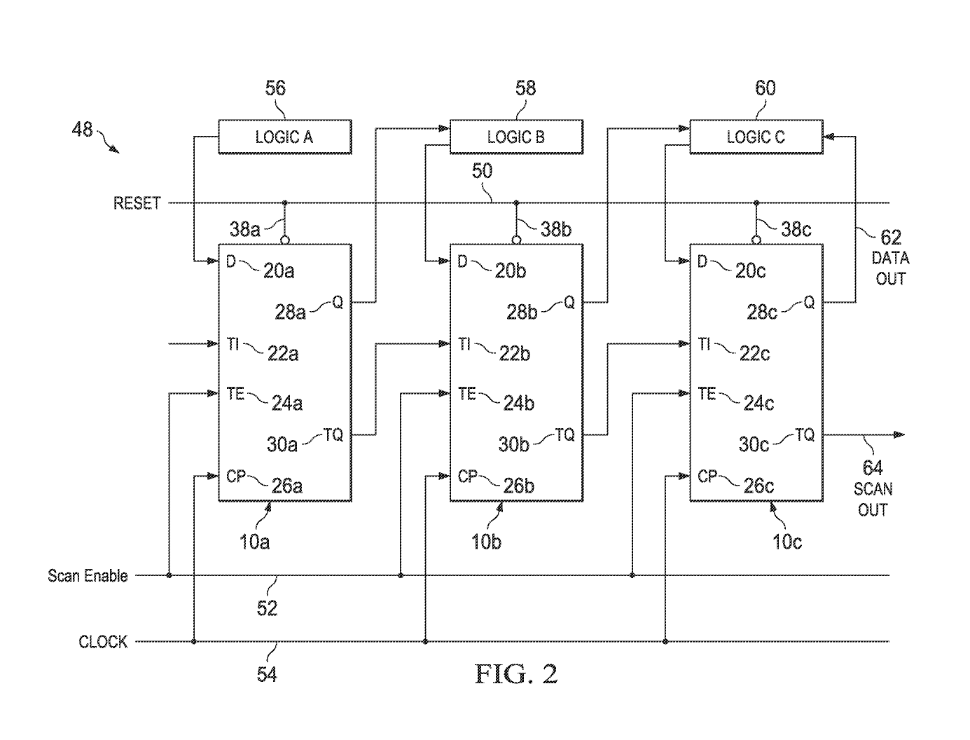

FIG. 2 illustrates a detailed representation of multiple flip-flop cells connected in series to each other in a scan chain configuration. Design 48 includes three flip-flop cells 10a, 10b, and 10c, representing three different instances of flip-flop cell 10 illustrated in FIG. 1. Each includes a data input D (20a, 20b, 20c); test input TI (22a, 22b, 22c); scan enable input TE (24a, 24b, 24c); clock input CP (26a, 26b, 26c), standard function flip-flop cell output Q (28a, 28b, 28c); and test flip-flop cell output TQ (30a, 30b, 30c). While design 48 depicts three flip-flop cells 10 in a scan chain configuration, embodiments are not limited to just three flip-flop cells 10. Rather, the shown configuration is scalable and can include additional flip-flop cells 10.

Though not shown, flip-flop cells 10a, 10b, and 10c each include an internal flip-flop (e.g., D flip-flop 12); internal logic gates (e.g., NOR gates 16 and 18); or internal multiplexer (e.g., multiplexer 14). For example, looking solely at flip-flop cell 10a, a multiplexer may be used to select between data input D 20a or test input TI 22a using scan enable signal 52 supplied to TE 24a as the multiplexer's selector. Data input 20a is passed through the multiplexer when TE 24a signals capture mode, and test input TI 22a is passed through the multiplexer when TE 24a signals scan shift mode. Similar multiplexers are included in flip-flop cells 10b and 10c.

Data input signals 20a, 20b, and 20c are received at data inputs D 20a, 20b, and 20c from Logic A 56, Logic B 58, and Logic C 60, respectively. Logic A, B, and C represent various circuitry and/or storage elements that use or receive data signals from flip-flop cells 10a, 10b, and 10c. In particular, the shown logic may include various circuit components (e.g., resistors, capacitors, inductors, etc.); logic gates (e.g., AND, OR, NAND, NOR, etc.); microcontrollers and microprocessors; ICs; systems on chip (SoC), etc. Storage elements may include one or more flip-flops (e.g., D, JK, SR, and the like) and/or hardware registers.

Reset lines 38a, 38b, 38c are each coupled to reset bus 50 that, in operation, sends a signal to reset the flip-flops in flip-flop cells 10a, 10b, and 10c. Clock inputs CP 26a, 26b, and 26c are each coupled to clock line 54, which provides a clock signal. Scan enable signal inputs TE 24a, 24b, and 24c are each coupled to a scan enable line 52 that provides a scan enable signal to switch flip-flops 10a, 10b, and 10c into either capture mode or scan shift mode. The scan enable signal may be switched from capture mode to scan shift mode manually by a user or periodically by a computing device or component thereof.

When triggered in scan shift mode flip-flop cells 10a, 10b, and 10c are configured to deny data inputs 20a, 20b, and 20c while passing test inputs TI 22a, 22b, and 22c through their respective flip-flop cells 10. Initial test input TI 22a represents an input signal from either another flip-flop cell 10 or some other source, such as a test signal generator. Embodiments may supply TI 22a with a signal that can be manipulated by a user (e.g., using a computing device, current source, or the like) or a signal that provides some predetermined testing pattern, like a square wave of a particular frequency.

Also while in scan shift mode, test inputs 22a, 22b, and 22c (or inversions thereof) are passed to test flip-flop cell outputs TQ 30a, 30b, and 30c. Test flip-flop cell outputs TQ 30a and 30b are supplied to test inputs TI 22b and 22c. Standard function flip-flop cell outputs Q 28a, 28b, and 28c are supplied to IC logic and circuitry Logic A 56, Logic B 58, and Logic C 60. Scan output 64 is generated and supplied to a storage element, hardware register, or the like where it can be stored, analyzed, and or displayed to a user to determine whether Logic A 56, Logic B 58, and Logic C 60 are functioning properly.

When in capture mode, TQ 30a, 30b, and 30c are each disabled by logic gates in flip-flop cells 10a, 10b, and 10c, respectively, driving these test flip-flop cell outputs to a particular value (e.g., 0, low, etc.). Also, Q 28a, 28b, and 28c are allowed to supply signals to Logic A 56, Logic B 58, and Logic C 60. When in scan shift mode, Q 28a, 28b, and 28c are each disabled by logic gates in flip-flop cells 10a, 10b, and 10c, driving these standard function flip-flop cell outputs to a particular value (e.g., 0, low, etc.). Also, TQ 30a, 30b, and 30c are supplied as test inputs TI 22 of the next flip-flop cell 10 in the scan chain series, with the last flip-flop cell 10c providing final scan output 64 to a memory element for storage in order to be compared to a reference value to see how logic and circuitry on the IC (e.g., Logic A 56, Logic B 58, and Logic C 60) is functioning. Performance results and an indication of the comparison to the reference value may be communicated to a user for evaluation.

Selective disablement of standard function flip-flop cell outputs Q 28a, 28b, and 28c and TQ 30a, 30b, and 30c reduces overall power consumption without sacrificing performance. The standard function flip-flop cell outputs are unnecessary during scan shift mode, and the test flip-flop cell outputs are unnecessary during capture mode. So there is no reason to allow the unnecessary flip-flop cell outputs to switch signals in modes where they do not matter.

It should be appreciated that the various embodiments disclosed herein are exemplary. Accordingly, various modifications to these embodiments may be made without departing from the scope of the present disclosure and the claims provided below. The subject matter of the present invention is described with specificity herein to meet statutory requirements. The description itself is not, however, intended to limit the scope of this patent. The claimed subject matter might also be embodied in other ways, to include different steps or combinations of steps similar to the ones described herein, in conjunction with other present or future technologies.

What is claimed is:

1. A circuit, comprising:
a first multiplexer configured to receive a data input, a test input, and a scan enable signal and provide a multiplexed output;
a first storage element configured to generate an internal data signal based on the multiplexed output and a clock signal; and
logic circuitry configured to produce a flip-flop cell output and a test flip-flop cell output based on the internal data signal and the enable signal.

2. The circuit of claim 1, wherein the logic circuitry comprises two NOR gates.

3. The circuit of claim 2, further comprising an inverter configured to invert the scan enable signal before the scan enable signal is supplied to one of the NOR gates.

4. The circuit of claim 2, wherein the internal data signal is inverted before being supplied to each of the NOR gates.

5. The circuit of claim 1, wherein the first storage element comprises at least one member of a group comprising a D flip-flop, a JK flip-flop, and an SR flip-flop.

6. The circuit of claim 1, further comprising:
a second multiplexer configured to generate a second multiplexed output based on a second data input, the test flip-flop cell output, and the scan enable signal;
a second storage element configured to generate a second internal data signal based on the second multiplexed output and the clock signal; and
additional logic circuitry configured to produce a second flip-flop cell output and a second test flip-flop cell output based on the second internal data signal and the enable signal.

7. The circuit of claim 6, wherein the additional logic circuitry comprises two additional NOR gates.

8. The circuit of claim 7, further comprising an inverter configured to invert the scan enable signal before the scan enable signal is supplied to one of the additional NOR gates.

9. The circuit of claim 6, wherein second storage element comprises at least one member of a group comprising a D flip-flop, a JK flip-flop, and an SR flip-flop.

10. The circuit of claim 6, wherein the scan enable signal is supplied to selector inputs of the first and second multiplexers.

11. A flip-flop cell, comprising:
a multiplexer configured to receive a data input, a test input, and a scan enable signal and provide a multiplexed output,
a flip-flop configured to generate an internal data signal based on the multiplexed output, and
a logic gate configured to generate a test flip-flop cell output based on the internal data signal and the scan enable signal, said test flip-flop cell output set to a fixed logic value if the scan enable signal is set to a first logic state and permitted to change state in response to said internal data signal if the scan enable signal is set to a second logic state.

12. The flip-flop of claim 11, wherein the logic gate comprises a NOR gate.

13. The flip-flop of claim 11, further including another logic gate configured to generate a standard function flip-flop cell output based on the internal data signal and the scan enable signal, said standard function flip-flop cell output set to the fixed logic value if the scan enable signal is set to the second logic state and permitted to change state in response to said internal data signal if the scan enable signal is set to the first logic state.

14. The flip-flop of claim 11, further comprising an inverter configured to generate an inversion of the scan enable signal for application to the logic gate.

15. An apparatus, comprising:
a plurality of flip-flop cells connected in series in a scan chain configuration, each flip-flop cell comprising:
a multiplexer configured to generate a multiplexed output based on a scan enable signal indicating either a scan shift mode or a capture mode,
a flip-flop receiving the multiplexed output and generating an internal flip-flop output,
a standard function flip-flop cell output configured to pass the internal flip-flop output in the capture mode and present a fixed logic state output in the scan shift mode, and
a test flip-flop cell output configured to pass an inversion of the internal flip-flop output in the scan shift mode and present a fixed logic state output in the capture mode.

16. The apparatus of claim 15, wherein the standard function flip-flop cell output is supplied to circuitry external to the flip-flop cell during capture mode.

17. The apparatus of claim 15, wherein the test flip-flop cell output is supplied to a test input of another flip-flop cell in the scan chain configuration.

18. The apparatus of claim 15, wherein each flip-flop cell in the scan chain configuration receives a data input signal from circuitry under test.

19. The apparatus of claim 15, wherein a first NOR gate is configured to generate a first signal for the test flip-flop cell output based on the internal data signal and the scan enable signal.

20. The apparatus of claim 19, wherein a second NOR gate is configured to generate a second signal for the standard function flip-flop cell output based on the internal data signal and the scan enable signal.
